(19) United States
(12) Patent Application Publication
(10) Pub. No.: US 2015/0179206 A1
(43) Pub. Date: Jun. 25, 2015

(54) TARGET MATERIAL AND METHOD OF PRODUCING THE SAME

(71) Applicant: HITACHI METALS, LTD., Minato-ku, Tokyo (JP)

(72) Inventors: Kouichi Sakamaki, Yasugi-shi (JP); Jun Fukuoka, Yasugi-shi (JP); Tomoyuki Hata, Yasugi-shi (JP); Kazuya Saito, Yasugi-shi (JP)

(21) Appl. No.: 14/416,278

(22) PCT Filed: Jul. 18, 2013
(86) PCT No.: PCT/JP2013/069565

§ 371 Date: Jan. 22, 2015

(30) Foreign Application Priority Data
Jul. 24, 2012 (JP) 2012-163186

(51) Int. Cl. G11B 5/851; C22C 38/12; C23C 14/14; B22F 5/00; C22C 33/02; H01J 37/34; C22C 38/10; B22F 3/14

(52) U.S. Cl. CPC G11B 5/851; C22C 38/10; C22C 38/12; B22F 3/14; B22F 5/00; C22C 33/0278; C22C 33/0285; H01J 37/3429; C23C 14/14; H01J 2237/332

(57) ABSTRACT

The invention provides a target material that represented by the composition formula in atomic percent of (Fe_{X}—Co_{100-X})_{100-Y}-M_{Y} (wherein M represents at least one element selected from Ta or Nb, and wherein X and Y respectively satisfy the conditions of 0≦X≦80 and 10≦Y≦30), that contains a balance of unavoidable impurities, and that has a flexural strain at break at 300° C. of 0.33% or more.

### TECHNICAL FIELD

The present invention relates to a target material suitable for forming, for example, a soft magnetic film in a magnetic recording medium and a method of producing the material.

### BACKGROUND ART

In recent years, perpendicular magnetic recording has been actually utilized as a means to increase recording density of magnetic recording media. In the perpendicular magnetic recording, a magnetic film of magnetic recording media is formed so as to orient the easy magnetic axes perpendicularly to the surface of medium. The perpendicular magnetic recording is useful for high recording density, because, even with increased recording density, the demagnetizing fields in the bits remain small, and the recording and reproducing characteristics are not substantially reduced. For perpendicular magnetic recording, magnetic recording media that include a magnetic recording film having improved recording sensitivity and a soft magnetic film have been developed.

Soft magnetic films for such magnetic recording media are required to have a high saturation flux density and an amorphous structure. Examples of the soft magnetic films include films of a Fe—Co alloy which contains Fe having a high saturation flux density as a main component and to which an element that promotes amorphization has been added.

These alloy films are required to have a high corrosion resistance. For formation of the alloy films, for example, Fe—Co based target materials for soft magnetic films have been proposed, the materials being a Fe—Co alloy that contains one or two elements selected from Nb or Ta at a concentration from 10 to 20 atom % (See Patent Document 1). In Patent Document 1, the Fe—Co based target material is produced by mixing pure-metal powder raw materials independently having a purity equal to or greater than 99.9% such that the resultant mixture has the composition of the target material and then by sintering the mixture.

### PRIOR ART DOCUMENT

### Patent Document

Patent Document 1: International Publication No. WO 2009/104509

### DISCLOSURE OF THE INVENTION

### Problem to be Solved by the Invention

During sputtering, since a target material is subjected to plasma discharge that leads to increased temperature, the target material is indirectly cooled from the back side of the material. In the case of sputtering at a high power to improve productivity, however, the indirect cooling from the back side of a target material may provide insufficient cooling of the target material, and the temperature of the target material may reach as high as 300° C. or higher.

As the Fe—Co based target material disclosed in Patent Document 1 is produced by adding an individual Ta or Nb powder to Fe and Co powders, the material can form a soft magnetic film that has high corrosion resistance in addition to a high saturation flux density and amorphous properties. Thus, a method that uses an Fe—Co based target material is a useful technique in facilitation of composition control.

However, it has been confirmed that sputtering of such Fe—Co based target material at a high input power caused the target material to crack during sputtering, which may make normal sputtering impossible.

The invention has been developed in view of the foregoing. In the above situations, there is a need for target materials that reduce the development of cracks in the case of sputtering the materials at a high input power.

There is also a need for a method of producing a target material that reduces the development of cracks in the case of sputtering the material at a high input power and that forms a soft magnetic film of magnetic recording media stably.

### Means for Solving the Problems

A study conducted by the present inventors has provided the following insights into the Fe—Co based target material disclosed in Patent Document 1.

In the microstructure of the Fe—Co based target material, large amounts of brittle intermetallic compounds that contain Ta/Nb at a high concentration are coarsely formed. Due to these brittle intermetallic compounds, the strain due to thermal expansion of the target material during sputtering at a high power exceeds the flexural strain at break at a high temperature, which results in development of cracks in the target material. As the result of various investigations that have been carried out in order to improve the flexural strain at break at a high temperature of target materials, the inventors have found a suitable composition and a suitable method of sintering a powder composition, thereby the invention was completed.

Following are specific means of solving the above problems. That is,

a first aspect of the invention is

<1> a target material that is represented by the composition formula in atomic percent of (Fe_{X}—Co_{100-X})_{100-Y}-M_{Y}, wherein M represents at least one element selected from Ta or Nb and X and Y respectively satisfy the conditions of 0≦X≦80 and 10≦Y≦30, that includes a balance of unavoidable impurities, and that has a flexural strain at break at 300° C. of 0.33% or more.

<2> in the target material as described in <1> above, the target material according to the first aspect preferably includes a metallurgical structure, wherein the metallurgical structure is observed in a cross section surface of the target material and has a maximum inscribed circle having a diameter of 20 μm or less, when the circle is drawn within a region of an intermetallic compound phase that contains at least one element selected from Ta or Nb.

A second aspect of the invention is

<3> a method of producing a target material, the method includes

pressure-sintering a powder composition under conditions of a sintering temperature of from 900° C. to 1400° C., a pressure of from 100 MPa to 200 MPa and a sintering time of from 1 to 10 hours,

the powder composition being represented by the composition formula in atomic percent of (Fe_{X}—Co_{100-X})_{100-Y}-M_{Y}, wherein M represents at least one element selected from Ta or Nb and X and Y respectively satisfy the conditions of 0≦X≦80 and 10≦Y≦30, and

the powder composition comprising a balance of unavoidable impurities and an alloy powder having a metallurgical structure observed in a cross section surface of the powder, the metallurgical structure having a maximum inscribed circle having a diameter of 10 μm or less, when the circle is drawn within a region of an intermetallic compound phase that contains at least one element selected from Ta or Nb.

In other words, the target material according to the first aspect can be obtained by pressure-sintering the above powder composition having the above composition formula at a temperature of from 900° C. to 1400° C. and a pressure of from 100 MPa to 200 MPa for a period of from about 1 to 10 hours.

<4> in the method of producing a target material as described in <3> above, the powder composition preferably includes a single-composition alloy powder adjusted such that the powder has a final composition.

### Effects of the Invention

The invention provides a target material that reduces the development of cracks in the case of sputtering at a high input power.

The invention also provides a method of producing a target material that reduces the development of cracks in the case of sputtering at a high input power and that forms a soft magnetic film of magnetic recording media stably.

### BRIEF DESCRIPTION OF DRAWINGS

FIG. 1 is a scanning electron micrograph of the microstructure of Sample 5, which is an example of the invention.

FIG. 2 is a scanning electron micrograph of the microstructure of Sample 10, which is an example of the invention.

FIG. 3 is a scanning electron micrograph of the microstructure of Sample 1, which is a comparative example of the invention.

FIG. 4 is a scanning electron micrograph of the microstructure of Sample 2, which is a comparative example of the invention.

FIG. 5 is a scanning electron micrograph of the microstructure of Sample 3, which is a comparative example of the invention.

FIG. 6 is a graph that shows the relationship between the flexural strain at break and the linear thermal expansion of Sample 1, which is a comparative example of the invention.

FIG. 7 is a graph that shows the relationship between the flexural strain at break and the linear thermal expansion of Sample 2, which is a comparative example of the invention.

FIG. 8 is a graph that shows the relationship between the flexural strain at break and the linear thermal expansion of Sample 3, which is a comparative example of the invention.

FIG. 9 is a graph that shows the relationship between the flexural strain at break and the linear thermal expansion of Sample 5, which is an example of the invention.

### DESCRIPTION OF EMBODIMENTS

The inventors have made various investigations focusing on the metallurgical structure and the mechanical properties at high temperature of target materials. During sputtering, since target materials are subjected to plasma discharge that leads to increased temperature, the target materials are indirectly cooled from the back side of the materials. In the case of sputtering at a high input power to improve deposition rate and then to improve productivity of a magnetic recording medium, however, if the cooling is carried out from the back side of a target material, the temperature of the target material is raised and reaches as high as 300° C. or higher.

The inventors have confirmed that, for example, clamping of an outer edge of a target material leads to strain due to thermal expansion when the temperature of the target material is high, and cracks were developed.

The invention is characterized in that the composition of a target material is optimized such that the material has a flexural strain at break at a certain temperature equal to or more than a certain value, the strain resulting from heat generation during sputtering, thereby inhibiting development of cracks in the target material. Now, the invention will be described in detail.

The target material of the invention has a flexural strain at break at 300° C. of 0.33% or more.

As used herein, the term flexural strain at break in the invention refers to the flexural strain on a material when the material breaks, as defined in, for example, JIS K7171. The flexural strain at break is determined by subjecting a test specimen taken from a target material to a 3-point bending test, measuring the deflection of the specimen at break, and calculating the strain by using Formula (1). In Formula (1) described below, ε_{fB} is the flexural strain at break, s_{B} is the deflection at break, h is the thickness of a test specimen, and L is the length between fulcrums. In the case of measuring a specimen at a high temperature of 300° C., a flex tester is equipped with a constant-temperature bath, and a test specimen is heated to 300° C. for measurement.

ε_{fB}=600 s_{B}h/L² (%) Formula (1)

The reason for setting the temperature at which the flexural strain at break ε_{fB} is determined at 300° C. in the invention is that in the case of sputtering at a high input power to improve productivity, the temperature of a target material during sputtering of 300° C. or higher is experimentally known to tend to develop cracks. Preferably, an alloy used in the invention has a linear thermal expansion at 300° C. of from 0.28% to 0.32%. A linear thermal expansion at 300° C. that exceeds the flexural strain at break causes the target material to crack during sputtering, which makes normal sputtering impossible.

In the invention, a target material having a flexural strain at break ε_{fB} at 300° C. of 0.33% or more, which exceeds the linear thermal expansion, can prevent the strain due to thermal expansion from exceeding the flexural strain at break ε_{fB}. This can reduce the development of cracks in the target material during sputtering. Preferably, the target material of the invention has a flexural strain at break ε_{fB} at 300° C. of 0.45% or more, in order to inhibit development of cracks in the target material during long and continuous sputtering.

The alloy on which the target material of the invention is based is represented by the composition formula in atomic percent of (Fe_{X}—Co_{100-X}), wherein X satisfies the condition of 0≦X≦80.

The reason for selecting the above alloy in the invention is that a binary alloy of Fe and Co exhibits the highest saturation magnetic moment among the various transition metal alloys in the so-called Slater-Pauling curve, which gives the saturation magnetic moment per one atom.

In a case in which the saturation magnetic moment needs to be maximized, the alloy preferably has an Fe atomic percent X in a range of from 50% to 80%. Because, in the composition ratio of Fe and Co (Fe:Co) in the alloy is about 65:35 at atomic ratio, the saturation magnetic moment becomes maximum and the Fe-Co alloy having an Fe atomic percent in a range of from 50% to 80% exhibits a high saturation magnetic moment.

In a case in which a thin film with reduced magnetostriction is desired, the target material preferably has a Fe atomic percent X of from 0% to 50%. Because, Co has a lower magnetostriction compared with Fe.

The target material of the invention contains one or both elements selected from Ta or Nb in a total amount of from 10 atom % to 30 atom %. Because, the Pourbaix diagram shows that such material forms a dense passive film over a broad pH range, and the material has the effect of improving corrosion resistance of a resulting soft magnetic film. Addition of one or both elements selected from Ta or Nb promotes amorphization during sputtering. In a case in which the one or both elements are added in a total amount of less than 10 atom %, the alloy is not amorphized. In a case in which the one or both elements are added in a total amount of more than 30 atom %, the magnetization reduced. Thus, the one or both elements are added in a total amount of from 10 atom % to 30 atom %.

In a case in which the one or both elements selected from Ta or Nb are added in an amount of more than 30 atom %, an intermetallic compound phase that contains one or both elements selected from Ta or Nb, which are brittle, is formed in a large amount, thereby it is difficult to provide a target material having a flexural strain at break ε_{fB} at 300° C. as described below of 0.33% or more. The one or both elements selected from Ta or Nb are added preferably in a total amount of from 16 atom % to 25 atom % and more preferably from 16 atom % to 20 atom %.

The target material of the invention contains a balance of Fe, Co, and unavoidable impurities, in addition to the one or both elements selected from Ta or Nb in an amount as described above. Desirably, the impurities are contained in as small an amount as possible. Desirably, oxygen and nitrogen, which are a gas component, are contained at a concentration equal to or less than 1000 ppm by mass. Desirably, incidental impurity elements other than the gas components, such as Ni, Si, and Al, are contained at a total concentration equal to or less than 1000 ppm by mass.

The target material of the invention has a metallurgical structure observed in a cross section surface of the target material, the structure having a maximum inscribed circle preferably having a diameter of 20 μm or less and more preferably 5 μm or less, in the case of drawing the circle within the region of an intermetallic compound phase that contains one or both elements selected from Ta or Nb.

As used herein, the term cross section surface refers to a cutting surface formed by cutting through the target material in any direction, and the term metallurgical structure refers to a metallurgical structure observed in such cutting surface.

If the maximum inscribed circle has a diameter of 20 μm or less, coarsening of an intermetallic compound phase that contains one or both elements of brittle Ta or Nb, which reduces the flexural strain at break ε_{fB}, can be prevented, thereby holding the flexural strain at break ε_{fB} at 300° C. at 0.33% or more.

Examples of intermetallic compound phases that contain at least one selected from Ta or Nb according to the invention include Fe₂Ta, FeTa, Fe₂Nb, FeNb, Co₇Ta, Co₂Ta, Co₆Ta₇, CoTa₂, Co₃Nb, Co₂Nb, Co₇Nb₆, and the like. Since these intermetallic compound phases are brittle, by reducing the diameter of the maximum inscribed circle drawn within the region of the coarse intermetallic compound present in the structure to 20 μm or less, the flexural strain at break ε_{fB} at 300° C. can be held at 0.33% or more.

Presence of an intermetallic compound phase that contains one or both elements selected from Ta or Nb in a cross section surface of the target material can be observed by, for example, X-ray diffraction or energy dispersive X-ray spectroscopy.

Preferably, the target material of the invention has a relative density of 99% or more. If the relative density is held at 99% or more by reducing defects such as voids present in the target material, local stress concentrations that tend to be produced by the defects are reduced, and reduction of the flexural strain at break ε_{fB} is prevented and thereby development of cracks can be prevented.

The term relative density in the invention refers to a value determined by dividing the “bulk density” that is measured according to the Archimedes principle by the theoretical density, which is a weighted average of the densities of the individual elements, the average calculated using the mass ratio obtained from the composition of the target material of the invention, and then by multiplying the resultant value by 100.

Preferably, the target material of the invention reduces residual stress. The pressure-sintering, machining after pressure-sintering, or blasting of outer edges in a process of producing the target material may cause the target material to store residual stress.

Increase of the residual stress may lead to reduction of the flexural strain at break ε_{fB}. In the invention, the target material preferably undergo subsequent processing such as heat treatment in order to release the residual stress in the material

The target material of the invention can be obtained by pressure-sintering a powder composition under conditions of a sintering temperature of from 900° C. to 1400° C., a pressure of from 100 MPa to 200 MPa and a sintering time of from 1 to 10 hours, the powder composition being represented by the composition formula in atomic percent of (Fe_{X}—Co_{100-X})_{100-Y}-M_{Y}, wherein M represents at least one element selected from Ta or Nb and X and Y respectively satisfy the conditions of 0≦X≦80 and 10≦Y≦30, and the powder composition comprising a balance of unavoidable impurities and an alloy powder having a metallurgical structure observed in a cross section surface of the powder, the metallurgical structure having a maximum inscribed circle having a diameter of 10 μm or less, when the circle is drawn within a region of an intermetallic compound phase that contains at least one element selected from Ta or Nb.

Generally, methods of producing a target material can be broadly classified into casting method and pressure-sintering method. In the casting method, the cast ingot has to be subjected to plastic deformation such as hot rolling in order to reduce casting defects present in a cast ingot that is used to form the target material and in order to uniformize the texture.

Alloys that contain Ta or Nb have a very poor hot workability, because a coarse intermetallic compound phase that contains at least one element selected from Ta or Nb is formed in the cooling process during the casting. Therefore, it is difficult to stably manufacture target materials.

To that end, in the invention, the specified powder composition is pressure-sintered under the above conditions to obtain the target material of the invention.

Examples of pressure-sintering methods that can be used herein include hot isostatic pressing, hot pressing, spark plasma sintering, and extrusion pressing and sintering. Among them, the hot isostatic pressing is suitable, because such pressing can steadily achieve pressure-sintering conditions described below.

In the invention, the sintering temperature is from 900° C. to 1400° C. If the sintering temperature is lower than 900° C., the sintering of the powder that contains at least one element selected from Ta or Nb, which are refractory metal, does not progress sufficiently, voids may be developed. If the sintering temperature is higher than 1400° C., the powder composition may melt. Therefore, in the invention, the sintering temperature is from 900° C. to 1400° C. The sintering temperature is preferably from 950° C. to 1300° C. in order to minimize formation of voids in the target material, to inhibit the growth of an intermetallic compound phase that contains one or more elements selected from Ta or Nb, and to increase the flexural strain at break ε_{fB}.

In the invention, the pressure is from 100 MPa to 200 MPa. If the pressure is less than 100 MPa, the composition cannot be sintered sufficiently, which tends to develop voids in the target material. If the pressure is more than 200 MPa, the residual stress is introduced into the target material during sintering. Therefore, in the invention, the pressure is from 100 MPa to 200 MPa. More preferably, the composition is sintered at a pressure of from 120 MPa to 160 MPa in order to minimize formation of voids, to inhibit introduction of the residual stress, and to increase the flexural strain at break ε_{fB}.

In the invention, the sintering time is a period of from 1 to 10 hours. If the sintering time is a period of less than an hour, the sintering cannot progress sufficiently, which makes it difficult to inhibit formation of voids. If the sintering time is a period of more than 10 hours, the production efficiency is markedly reduced. Therefore, in the invention, the powder composition is sintered for a period of from 1 to 10 hours. More preferably, the composition is sintered for a period of from 1 to 3 hours in order to minimize formation of voids, to inhibit growth of an intermetallic compound phase that contains one or more elements selected from Ta or Nb, and to increase the flexural strain at break ε_{dB}.

The powder composition in the invention can be any of an alloy powder of multiple types of alloy powders including alloy particles having a metallurgical structure observed in a cross section surface of the target material, the structure having a maximum inscribed circle preferably having a diameter of 10 μm or less, in the case of drawing the circle within the region of an intermetallic compound phase that contains one or both selected from Ta or Nb; a mixed powder prepared by mixing pure metal particles with the above alloy powder such that the resultant has the final composition; or an alloy powder of a single type of particles adjusted such that the resultant has the final composition.

For example, in a method in which a mixed powder prepared by mixing multiple types of alloy powders such that the resultant has the final composition is pressure-sintered as the powder composition, the resultant target material can have a flexural strain at break ε_{fB} at 300° C. of 0.33% or more. And, by adjusting the types of powders to be mixed, the permeability of the target material can be reduced. Then, high magnetic leakage flux is provided from the back side cathode, the effect improving usage efficiency can be obtained.

Preferably, the alloy powder used in the invention has an average particle diameter of from 10 μm to 200 μm. Use of the alloy powder having an average particle diameter in the above range allows the target material of the invention to have a flexural strain at break ε_{fB} at 300° C. of 0.33% or more and allows reduction of a metallic phase selected from a pure Ta phase or a pure Nb phase or both of the phases remaining in the structure of the target material, thereby particle defects during sputtering can be also reduced.

In the invention, the average particle diameter of an alloy powder refers to the sphere-equivalent diameter determined by the light scattering method using laser light, as specified in JIS Z 8901. The average particle diameter represents the diameter (D50) determined by dividing the cumulative particle size distribution into two equal volumes (50%).

Depending on the amount of the elements added, the target material of the invention can be produced by using a mixed powder prepared by mixing one or more types of powders selected from Fe—Co—Ta/Nb alloy powder or Co—Ta/Nb alloy powder. Particularly, in the case of using an alloy component that contains Ta and Nb, which are refractory metal, in a total amount of more than 18 atom %, since the melting point is increased, it may be difficult to produce a single-composition alloy powder adjusted such that the powder has the final composition. Therefore, in the invention, the mixed powder described above can be used and pressure-sintered to obtain the target material.

The one or more powders that are selected from pure Ta powder or pure Nb powder and that are mixed with the alloy powder desirably has an average particle diameter of from 1 μm to 15 μm. If at least one selected from pure Ta powder or pure Nb powder has an average particle diameter of 15 μm or less, one or more types of metallic phases selected from a pure Ta phase or a pure Nb phase are less likely to remain in the target material after pressure sintering, particle defects during sputtering are reduced. And initiating points of cracks in an intermetallic compound phase that contains at least one element selected from Ta or Nb are less likely to be developed, which the points being formed around the above phases. This can prevent reduction in the flexural strain at break ε_{fB}. If at least one powder selected from pure Ta powder or pure Nb powder has an average particle diameter of more than 1 μm, the filling capability can be favorably maintained.

Like the average particle diameter of the alloy powder, the average particle diameter of the pure Ta powder and the pure Nb powder is the equivalent spherical diameter (D50) determined by the light scattering method using laser light, as specified in JIS Z 8901.

Preferably, the target material of the invention is produced by using a single-composition alloy powder adjusted such that the powder has a final composition as a powder composition. This can provide the effect of more stably, finely, and homogenously dispersing an intermetallic compound phase that contains at least one element selected from Ta or Nb, in the target material of the invention. As the result, the flexural strain at break ε_{fB} at 300° C. can be more increased.

The single-composition alloy powder adjusted such that the powder has a final composition is preferably produced by, for example, gas atomization, which can provide a rapidly solidified structure. In the invention, the gas atomization is used to produce the alloy powder, the alloy powder is produced by tightly controlling the size and the cooling rate of droplets to be produced in the gas atomization, and the obtained alloy powder can have a maximum inscribed circle having a diameter of 10 μm or less, in the case of drawing the circle within the region of an intermetallic compound phase that contains at least one element selected from Ta or Nb.

The term “single composition adjusted such that the powder has a final composition” in the invention refers to an alloy composition obtained after tapping the entire alloy melt adjusted such that the alloy has the final composition, into a melting crucible, in a case in which the gas atomization is employed.

By using an alloy powder that has a maximum inscribed circle having a diameter of 10 μm or less, when the circle is drawn within the region of an intermetallic compound phase that contains at least one element selected from Ta or Nb, if the target material is produced by pressure-sintering under the conditions described above, a structure that has a maximum inscribed circle having a diameter of 20 μm or less can be obtained, when the circle is drawn within the region of an intermetallic compound phase in the target material, the phase containing at least one selected from Ta or Nb. And, the flexural strain at break ε_{dB} at 300° C. can be increased.

### EXAMPLES

Now, the invention will be more specifically described with reference to Examples, although the invention is not limited to Examples below, without departing from the spirit of the invention.

### Example 1

As Samples 4-9, which were an example of the invention, an Fe—Co—Ta alloy powder was used to prepare a powder represented by the composition formula in atomic percent of (Fe_{X}—Co_{100-X})_{100-Y}—TaY (0≦X≦80, 10≦Y≦30), according to the respective combinations illustrated in Table 1.

For Samples 1-3, which were a comparative example, pure Fe, pure Co, pure Ta, an Fe—Co—Ta alloy powder, and a Co—Ta alloy powder were used as raw materials to prepare a powder having the composition formula in atomic percent of (Fe₆₅—Co₃₅)_{(100-Y)}—Ta_{Y} (Y=18).

The Fe—Co—Ta alloy powder and the Co—Ta alloy powder were powders that were produced by gas atomization and that had an average particle diameter (D50) of 100 μm.

In Table 1 below, the pure Ta powder was a commercially available Ta powder that was produced by mechanical comminution and that had an average particle diameter (D50) of 30 μm. The pure Co powder was a commercially available Co powder that was produced by mechanical comminution and that had an average particle diameter (D50) of 120 μm. The pure Fe powder was a commercially available Ta powder that was produced by mechanical comminution and that had an average particle diameter (D50) of 120 μm.

In the metallurgical structure observed in a cross section surface of each of the particles of each of the alloy powders, the diameter of the maximum inscribed circle drawn within the region of an intermetallic compound phase that contained Ta was observed and determined by an electron scanning microscope (JSM-6610LA by JEOL Ltd.).

Each of the mixed powders obtained as described above was placed in a pressure vessel made of a soft steel. After evacuation and sealing, the powder was sintered by hot isostatic pressing at the temperature and the pressure illustrated in Table 1 for the period illustrated in Table 1 to obtain a sintered body having a diameter of 194 mm and a thickness of 14 mm.

As Sample 2 for comparison, the composition described above was melted in a vacuum induction-melting furnace at 1680° C. and casted (the casting method) to produce an ingot having a diameter of 200 mm and a thickness of 30 mm.

A test specimen having a dimension of 10 mm×10 mm×5 mm was taken from a scrap of each of the sintered bodies produced as described above. After removal of contaminants such as black scale entire mill scale, the density of the test specimen was determined by an electronic densimeter SD-120L (by Kensei Co., Ltd.) according to the Archimedes principle. Then, the resulting bulk density and the theoretical density were used to calculate the relative density (%, =bulk density/theoretical density×100), as described above. The resultant relative densities are illustrated in Table 1.

As illustrated in Table 1, it was confirmed that Samples 4-9, which were an example of the invention, and Samples 1-3, which were a comparative example of the invention, were a high density target material having a relative density of more than 100%.

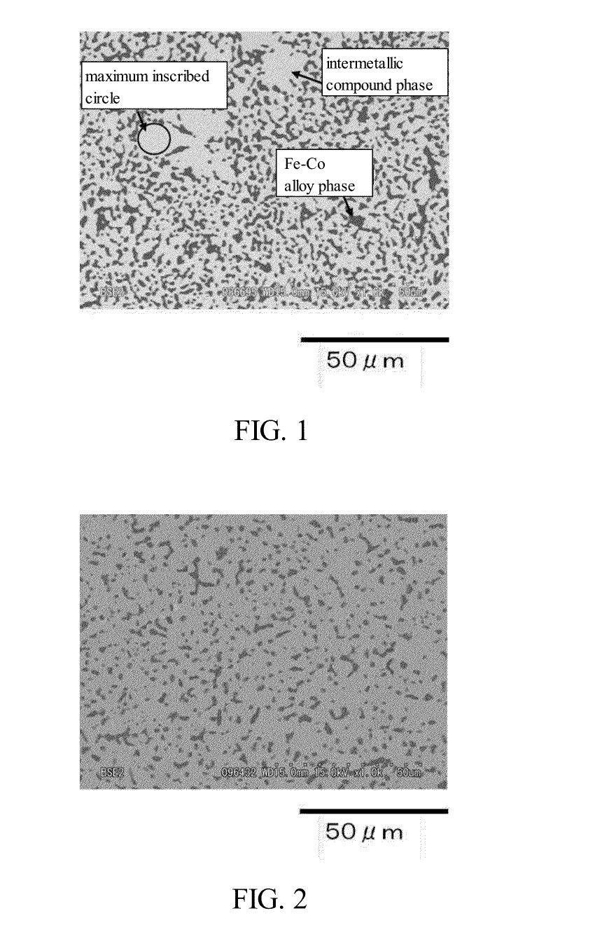

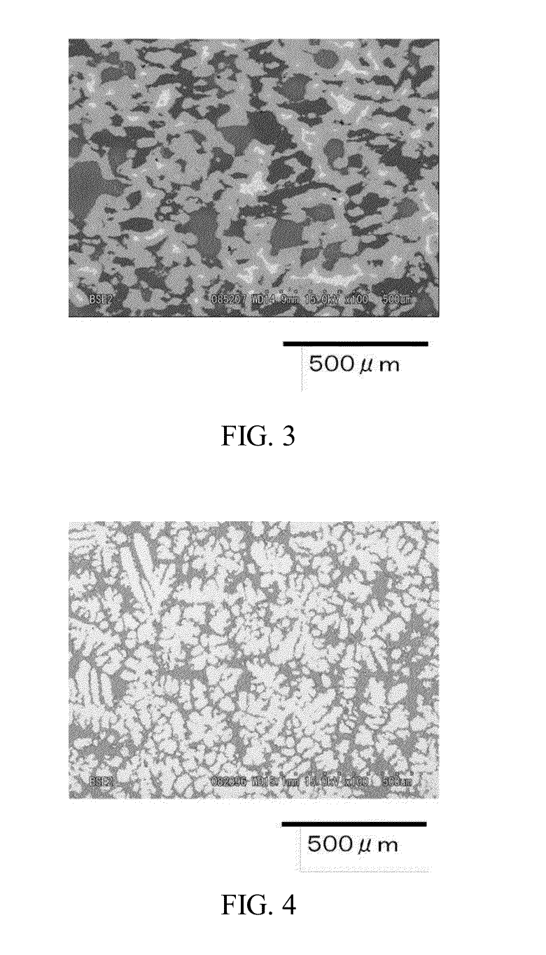

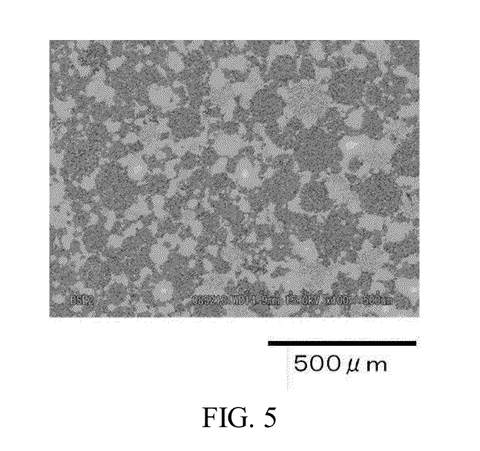

For microstructure observation, a sample was taken from each of the sintered bodies and ingots produced as described above, and the microstructures were observed by an electron scanning microscope (JSM-6610LA by JEOL Ltd.) with a field of view of 2.2 mm². As illustrated by a measurement example illustrated in FIG. 1, the diameter of the maximum inscribed circle drawn within the region of a Ta intermetallic compound phase was determined. The results are illustrated in Table 1. The microstructures observed in Samples 5, 1, 2, and 3 are respectively illustrated in FIGS. 1, 3, 4, and 5.

In FIGS. 1, 3, 4, and 5, white parts are a pure Ta phase, light gray parts are an intermetallic compound phase that contains Ta, and the balance is a Fe—Co alloy phase that is substantially free of Ta.

As illustrated in Table 1 (in the column “Diameter of Maximum Inscribed Circle in Intermetallic Compound Phase of Sintered Body”), each of the sintered bodies had a maximum inscribed circle having a diameter of 20 μm or less, when the circle is drawn within the region of an intermetallic compound phase that contained Ta or Nb. This confirmed that the intermetallic compound phase that contained Ta was a fine phase.

In contrast, it was confirmed that the target materials that were a comparative example had a coarse intermetallic compound phase that had a maximum inscribed circle having a diameter of more than 20 μm, when the circle is drawn within the region of an intermetallic compound phase that contained Ta.

For 3-point bending tests, a test specimen having a length of 70 mm, a width of 5 mm, and a thickness of 5 mm was taken from each of the sintered bodies produced as described above, and then 3-point bending tests were performed at a crosshead speed of 1.0 mm/min, a span length of 50 mm, and a respective temperature (room temperature (25° C.), 200° C., 300° C., 400° C., or 500° C.) using a servo hydraulic high temperature fatigue tester EFH50-5 (by Saginomiya Seisakusho, Inc.). The deflection at break was determined from the flexure load-deflection curve obtained, and then Formula (1) described above was used to calculate the flexural strain at break ε_{fB} at the respective temperatures.

A test specimen having a diameter of 5.0 mm and a length of 19.5 mm was taken from the sintered bodies produced as described above, and the linear thermal expansion was measured under an Ar gas atomosphere at the respective temperatures using a thermo-mechanical analyzer (TMA-8140C by Rigaku Corp.).

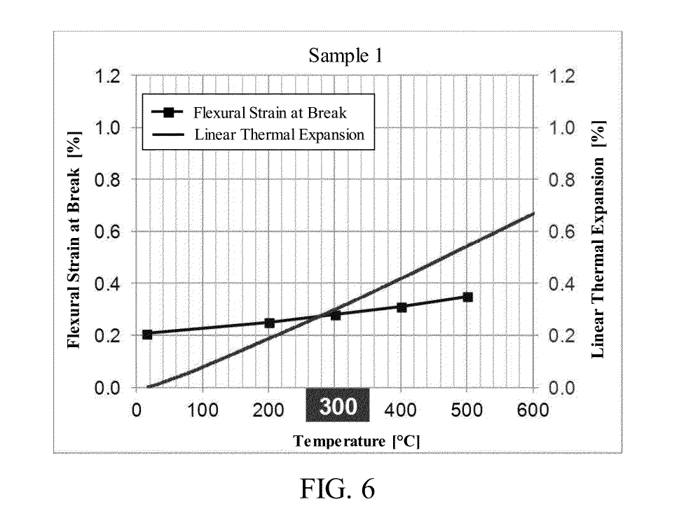

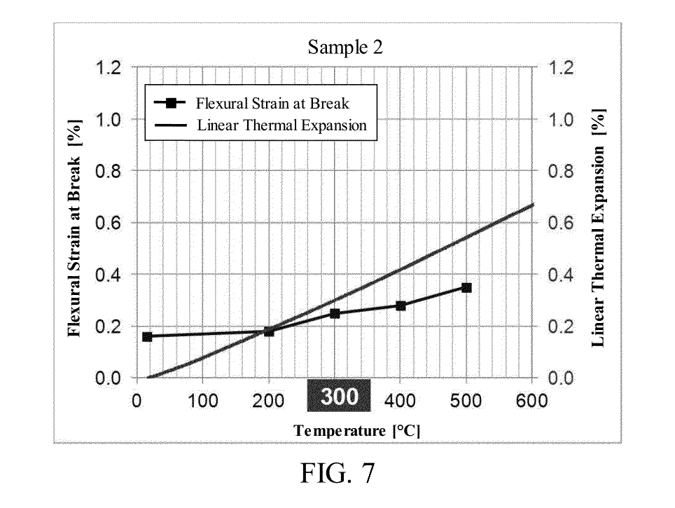

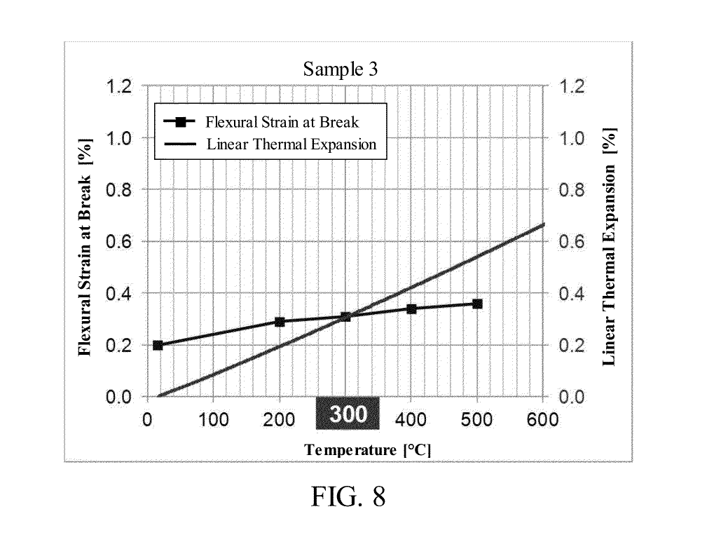

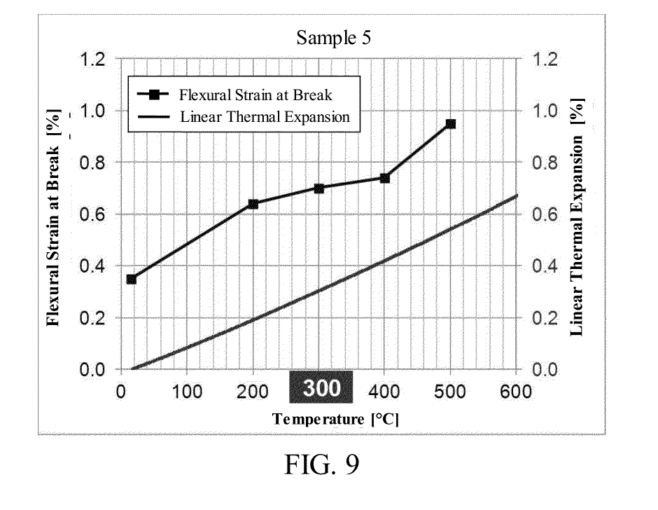

The flexural strain at break ε_{fB} and the linear thermal expansion at the respective temperatures of Samples 1, 2, 3, and 5 are respectively illustrated in FIGS. 6, 7, 8, and 9, and the flexural strain at break ε_{fB} at 300° C. is illustrated in Table 1.

It was confirmed that Samples 4-9, which were an example of the invention, had a markedly increased flexural strain at break ε_{fB} at each of the temperatures due to homogenous and fine dispersion of the intermetallic compound phase that contained Ta.

Each of the sintered bodies obtained as described above was machined into a target material having a diameter of 180 mm and a thickness of 4 mm.

The target materials of Samples 1-9 produced as described above were placed in a chamber of a DC magnetron sputtering device (C3010 by Canon Anelva Corp.). After the chamber was evacuated to a base vacuum equal to or less than 2×10⁻⁵ Pa, discharge was continuously generated at an Ar gas pressure of 0.6 Pa and an input power of 1500 W for a period of 120 seconds. Under these conditions, the materials were sputtered at a high power for a long period of time, and the above conditions were severer than a high power sputtering condition at an input power of about 1000 W, the condition being usually used for improving productivity. Therefore, the above conditions were useful for determining crack resistance of the target materials.

After sputtering under the above conditions, the chamber was opened to the atmosphere. Then, the target materials of Samples 1-9 were removed from the sputtering device and examined if the materials had a crack. It was confirmed that the target materials of Samples 1-3, which were a comparative example of the invention, had a crack. In contrast, it was confirmed that the target materials of Samples 4-9, which were an example of the invention, had no cracks, and that the invention is effective.

TABLE 1

| | | | | Diameter of | | | | | Diameter of | | | |
|---|---|---|---|---|---|---|---|---|---|---|---|---|
| | | | | Maximum | | | | | Maximum | | | |
| | | | | Inscribed | | | | | Inscribed | | | |
| | | | | Circle in | | | | | Circle in | | | |
| | | | | Intermetallic | | | | | Intermetallic | Flexural | | |
| | | | | Compound | Sinter- | | | | Compound | Strain at | | |
| | | | | Phase of | ing | Sinter- | Sinter- | | Phase of | Break | | |
| | Composition of Raw Powder | | | Alloy | Tem- | ing | ing | Relative | Sintered | ε_{fB} at | Presence | |
| Sample | [atom %] | | | Powder | perature | Pressure | Period | Density | Body | 300° C. | of Crack | |
| No. | 1 | 2 | 3 | [μm] | [° C.] | [MPa] | [Hr] | [%] | [μm] | [%] | in Target | Note |
| 1 | Pure Fe | Pure Co | Pure | — | 1250 | 120 | 2 | 101.4 | 68 | 0.25 | Yes | Comparative |
| | | | Ta | | | | | | | | | Example |
| 2 | Casting Method | | | — | — | — | — | 102.6 | 55 | 0.18 | Yes | Comparative |
| | | | | | | | | | | | | Example |
| 3 | Fe17.2Co14.0Ta | Co16.0Ta | Pure | 21 | 1250 | 150 | 3 | 101.6 | 61 | 0.32 | Yes | Comparative |
| | | | Ta | | | | | | | | | Example |
| 4 | Fe28.7Co18.0Ta | — | — | 3 | 950 | 120 | 1 | 101.7 | 6 | 0.48 | No | Example of |
| | | | | | | | | | | | | Invention |
| 5 | Fe28.7Co18.0Ta | — | — | 3 | 1250 | 150 | 1 | 101.7 | 11 | 0.64 | No | Example of |
| | | | | | | | | | | | | Invention |
| 6 | Fe28.7Co18.0Ta | — | — | 3 | 1250 | 150 | 3 | 101.7 | 7 | 0.61 | No | Example of |
| | | | | | | | | | | | | Invention |
| 7 | Fe29.0Co18.0Ta | — | — | 4 | 1250 | 150 | 5 | 101.8 | 4 | 0.70 | No | Example of |
| | | | | | | | | | | | | Invention |
| 8 | Fe29.0Co18.0Ta | — | — | 3 | 1250 | 120 | 10 | 101.8 | 12 | 0.53 | No | Example of |
| | | | | | | | | | | | | Invention |
| 9 | Fe28.5Co18.5Ta | — | | 4 | 1250 | 120 | 10 | 101.8 | 9 | 0.64 | No | Example of |
| | | | | | | | | | | | | Invention |

### Example 2

### Sample 10

First, an alloy powder that had the composition formula in atomic percent of Fe₅₁—Co₂₇—Nb₂₂ and an average particle diameter (D50) of 100 μm was produced by gas atomization.

In the metallurgical structure observed in a cross section surface of the particles of the alloy powder, the diameter of the maximum inscribed circle drawn within the region of an intermetallic compound phase that contained Nb was observed and determined by an electron scanning microscope (JSM-6610LA by JEOL Ltd.). The diameter of the maximum inscribed circle was measured to be 4 μm.

The alloy powder was placed in a pressure vessel made of a soft steel. After evacuation and sealing, the powder was sintered by hot isostatic pressing at a temperature of 1250° C. and a pressure of 150 MPa for a period of an hour to obtain a sintered body having a diameter of 194 mm and a thickness of 14 mm.

A test specimen having a dimension of 10 mm×10 mm×5 mm was taken from a scrap of the sintered body. After removal of contaminants such as black scale, the density of the test specimen was determined by an electronic densimeter SD-120L (by Kensei Co., Ltd.) according to the Archimedes principle. Then, the resulting bulk density and the theoretical density were used to calculate the relative density (%, =bulk density/theoretical density×100), as described above. The resultant relative density was 102.2%, it was confirmed that the sintered body is useful as a high density target material.

For microstructure observation, a sample was taken from the sintered body produced as described above, and the microstructure was observed by an electron scanning microscope (JSM-6610LA by JEOL Ltd.) with a field of view of 2.2 mm². The result is illustrated in FIG. 2.

In FIG. 2, white parts are a pure Nb phase, light gray parts are an intermetallic compound phase that contains Nb, and the balance is a Fe—Co alloy phase that is substantially free of Nb. The target material produced according to the invention had a metallurgical structure observed in a cross section surface of the target material, which the structure having a maximum inscribed circle having a diameter of 12 μm, when the circle is drawn within the region of an intermetallic compound phase that contained Nb. This confirmed that the intermetallic compound phase that contained Nb was a fine phase.

The sintered body obtained as described above was machined into a target material having a diameter of 180 mm and a thickness of 4 mm.

The target material was placed in a chamber of a DC magnetron sputtering device (C3010 by Canon Anelva Corp.). After the chamber was evacuated to a base vacuum equal to or less than 2×10⁻⁵ Pa, discharge was continuously generated at an Ar gas pressure of 0.6 Pa and an input power of 1500 W for a period of 120 seconds. Under these conditions, the material was sputtered at a high power for a long period of time, and the above conditions were severer than a high power sputtering condition at an input power of about 1000 W, the condition being usually used for improving productivity. Therefore, the above conditions were useful for determining crack resistance of the target material.

After sputtering under the above conditions, the chamber was opened to the atmosphere. Then, the target material was removed from the sputtering device and examined if the materials had a crack. It was confirmed that the target material produced according to the invention had no cracks even after sputtering and that the invention was effective.

The disclosure of Japanese Patent Application No. 2012-163186 is incorporated herein by reference in its entirety.

All publications, patent applications, and technical specifications described herein are herein incorporated by reference to the same extent as if individual publication, patent application, and technical specification were specifically and individually indicated to be incorporated by reference.

1. A target material that is represented by the composition formula in atomic percent of (Fe_{X}—Co_{100-X})_{100-Y}-M_{Y}, wherein M represents at least one element selected from Ta or Nb and X and Y respectively satisfy the conditions of 0≦X≦80 and 10≦Y≦30, that comprises a balance of unavoidable impurities, and that has a flexural strain at break at 300° C. of 0.33% or more.

2. The target material according to claim 1, comprising a metallurgical structure, wherein the metallurgical structure is observed in a cross section surface of the target material and has a maximum inscribed circle having a diameter of 20 μm or less, when the circle is drawn within a region of an intermetallic compound phase that contains at least one element selected from Ta or Nb.

3. A method of producing a target material, the method comprising:
pressure-sintering a powder composition under conditions of a sintering temperature of from 900° C. to 1400° C., a pressure of from 100 MPa to 200 MPa and a sintering time of from 1 to 10 hours,
the powder composition being represented by the composition formula in atomic percent of (Fe_{X}—Co_{100-X})_{100-Y}-M_{Y}, wherein M represents at least one element selected from Ta or Nb and X and Y respectively satisfy the conditions of 0≦X≦80 and 10≦Y≦30, and
the powder composition comprising a balance of unavoidable impurities and an alloy powder having a metallurgical structure observed in a cross section surface of the powder, the metallurgical structure having a maximum inscribed circle having a diameter of 10 μm or less, when the circle is drawn within a region of an intermetallic compound phase that contains at least one element selected from Ta or Nb.

4. The method of producing a target material according to claim 3, wherein the powder composition comprises a single-composition alloy powder adjusted such that the powder has a final composition.
